(19) United States
(12) Patent Application Publication
(10) Pub. No.: US 2025/0046576 A1
(43) Pub. Date: Feb. 6, 2025

(54) PLASMA PROCESSING ASSEMBLY FOR RF AND PVT INTEGRATION

(71) Applicant: Applied Materials, Inc., Santa Clara, CA (US)

(72) Inventors: Yue GUO, Redwood City, CA (US); Yang YANG, San Diego, CA (US); A N M Wasekul AZAD, Santa Clara, CA (US); Kartik RAMASWAMY, San Jose, CA (US); Nicolas J. BRIGHT, Arlington, WA (US)

(21) Appl. No.: 18/365,261

(22) Filed: Aug. 4, 2023

(51) Int. Cl. H01J 37/32

(52) U.S. Cl. CPC H01J 37/32183; H01J 37/32128; H01J 37/32146; H01J 2237/3341

(57) ABSTRACT

Embodiments of the present disclosure relate to a system and methods for processing a substrate in a plasma processing system. In an embodiment a plasma processing system is provided that includes a radio frequency (RF) generator coupled to a substrate support base disposed within the plasma processing system and configured to deliver an RF signal to the substrate support base, a pulsed voltage (PV) waveform generator coupled the substrate support base and configured to deliver a PV waveform to the substrate support base while the RF signal is delivered to the substrate support base, and a high voltage supply coupled to a biasing electrode of the plasma processing system and configured to deliver a chucking voltage to a biasing electrode disposed with the plasma processing system.

### BACKGROUND

### Field

Embodiments of the present invention generally relate to a system and methods used in semiconductor device manufacturing. More specifically, embodiments provided herein generally include a system and methods for processing a substrate in a plasma processing system.

### Description of the Related Art

Reliably producing high aspect ratio features is one of the key technology challenges for the next generation of semiconductor devices. One method of forming high aspect ratio features uses a plasma assisted etching process, such as a reactive ion etch (RIE) plasma process, to form high aspect ratio openings in a material layer, such as a dielectric layer, of a substrate. In a typical RIE plasma process, a plasma is formed in a processing chamber and ions from the plasma are accelerated towards a surface of a substrate to form openings in a material layer disposed beneath a mask layer formed on the surface of the substrate.

A typical Reactive Ion Etch (RIE) plasma processing chamber includes a radio frequency (RF) bias generator, which supplies an RF voltage to a power electrode. In a capacitively coupled gas discharge, the plasma is created by using a radio frequency (RF) generator that is coupled to the power electrode that is disposed within an electrostatic chuck (ESC) assembly or within another portion of the processing chamber. Typically, an RF matching network (“RF match”) tunes an RF waveform provided from an RF generator to deliver RF power to an apparent load of 500 to reduce the reflected power and improve the power delivery efficiency. If the impedance of the load is not properly matched to impedance of the source (e.g., the RF generator), a portion of the RF waveform can reflect back in the opposite direction along the same transmission line.

A number of plasma processes also utilize DC voltage pulsing schemes to control the plasma sheath disposed over the substrate that is being processed. During operation, high DC voltage pulses are provided by a high voltage DC supply that are used to provide a negative bias to a biasing electrode while a pulsed voltage (PV) waveform are provided by a PV waveform generated to the biasing electrode simultaneously. The voltage provided to the biasing electrode is equal to the sum of the high DC voltage pulses and the PV waveform. The summing of voltages on the biasing electrode causes overshoots and droops in the combined waveform provided to the biasing electrode. The overshoots cause a high current (current spikes) in the combined waveform and arcing due to an increases electric field experienced at the edges of the biasing electrode.

Thus, there is a need in the art for plasma processing devices that are at least able to resolve the issues outlined above.

### SUMMARY

In an embodiment a plasma processing system is provided that includes a radio frequency (RF) generator coupled to a substrate support base disposed within the plasma processing system and configured to deliver an RF signal to the substrate support base, a pulsed voltage (PV) waveform generator coupled the substrate support base and configured to deliver a PV waveform to the substrate support base while the RF signal is delivered to the substrate support base, and a high voltage supply coupled to a biasing electrode of the plasma processing system and configured to deliver a chucking voltage to a biasing electrode disposed with the plasma processing system.

In another embodiment a plasma processing system is provided that includes a radio frequency (RF) generator configured to generate an RF signal, a pulsed voltage (PV) waveform generator configured to generate a PV waveform, a high voltage supply configured to generate a chucking voltage, and a junction box coupled to the RF generator, the PV waveform generator, and the high voltage supply, the junction box configured to receive the RF signal, the PV waveform, and the chucking voltage, supply the RF signal and the PV waveform to a substrate support base of the plasma processing system, and supply the chucking voltage to a biasing electrode of the plasma processing system.

In another embodiment a junction box includes a radio frequency (RF) filter coupled to an RF generator of a plasma processing system and configured to receive an RF signal from the RF generator, a pulsed voltage (PV) filter coupled to a PV waveform generator of the plasma processing system and configured to receive an PV waveform from the PV waveform generator, and a bias compensation module (BCM) coupled to a high voltage supply of the plasma processing system and configured to receive a chucking voltage from the high voltage supply, wherein the junction box is configured to transmit the RF signal and the PV waveform to a substrate support base of a plasma processing chamber of the plasma processing system and transmit the chucking voltage to a biasing electrode of the plasma processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a simplified schematic representation of a plasma processing system, according to one or more embodiments.

FIG. 1B is a schematic cross-sectional view of a plasma processing system that can be configured to perform one or more of the plasma processing methods described herein, according to one or more embodiments.

FIG. 2 illustrates voltage pulses provided within a voltage waveform that is established at a substrate due to the delivery of voltage pulses to a biasing electrode during plasma processing, according to one or more embodiments

FIGS. 3A-3C are schematic representations of a junction box of the plasma processing system, according to one or more embodiments.

FIG. 4 is a schematic representation of a RF power delivery system, according to one or more embodiments

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a system used in a semiconductor device manufacturing process. More specifically, embodiments provided herein generally include apparatus and methods for reducing the current provided to a biasing electrode of a plasma processing chamber to reduce the probability of arcing and to increase the margin of the voltage provided to the plasma processing chamber.

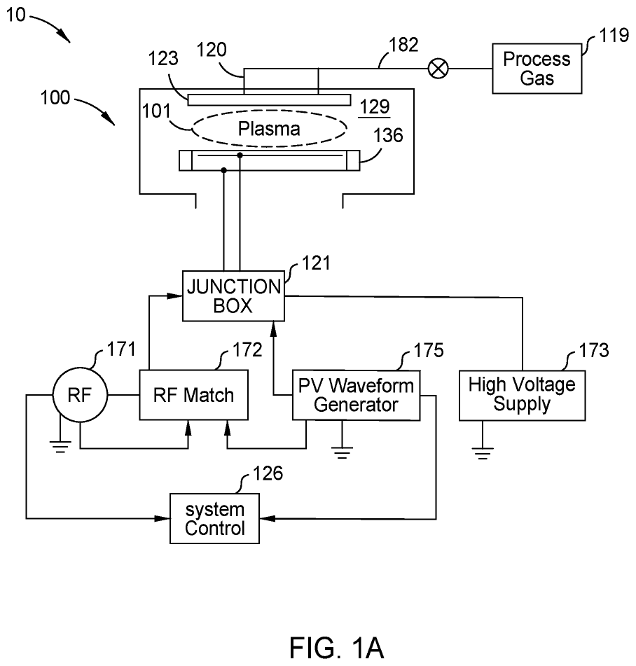

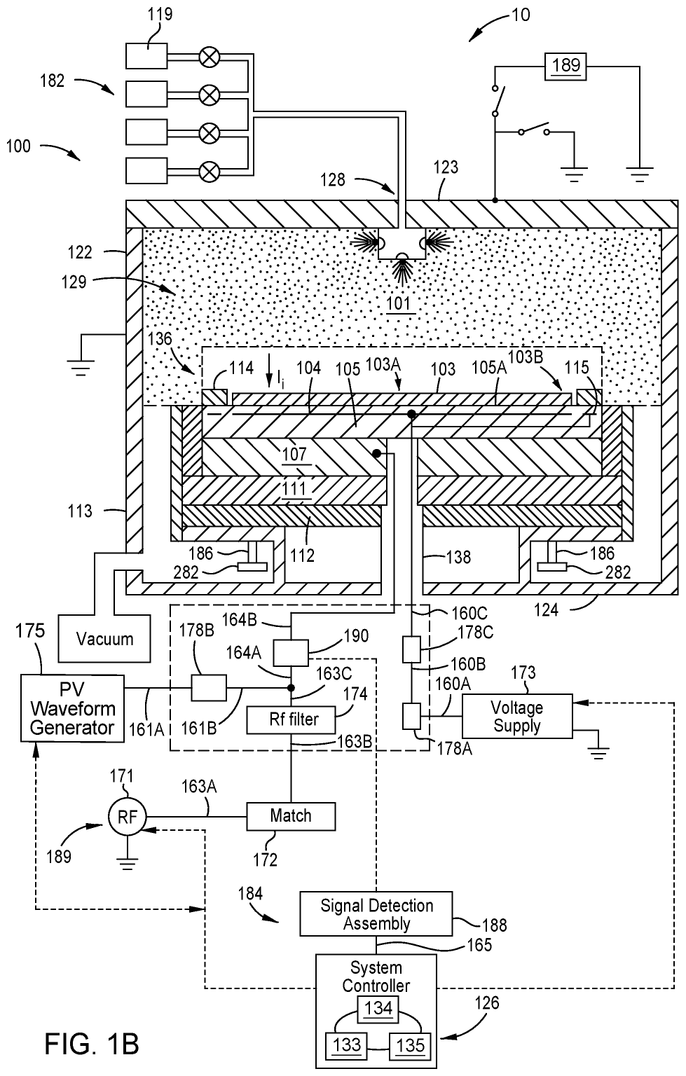

FIG. 1A is a schematic representation of a plasma processing system. The plasma processing system 10 is configured for plasma-assisted etching processes, such as a reactive ion etch (RIE) plasma processing. The plasma processing system 10 can also be used in other plasma-assisted processes, such as plasma-enhanced deposition processes (for example, plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping (PLAD) processing. In one configuration, as shown in FIG. 1A, the plasma processing system 10 is configured to form a capacitive coupled plasma (CCP). However, in some embodiments, a plasma may alternately be generated by an inductively coupled source disposed over a processing region of the plasma processing system 10.

The plasma processing system 10 includes a processing chamber 100, a substrate support assembly 136, a gas delivery system 182, a high voltage supply 173, a radio frequency (RF) generator 171, and an RF match 172 (e.g., RF impedance matching network). A chamber lid 123 includes one or more sidewalls and a chamber base that are configured to withstand the pressures and energy applied to them while a plasma 101 is generated within a vacuum environment maintained in a processing volume 129 of the processing chamber 100 during processing.

The gas delivery system 182, which is coupled to the processing volume 129 of the processing chamber 100, is configured to deliver at least one processing gas from at least one gas processing source 119 to the processing volume 129 of the processing chamber 100. The gas delivery system 182 includes the processing gas source 119 and one or more gas inlets 128 positioned through the chamber lid 123. The gas inlets 128 are configured to deliver one or more processing gasses to the processing volume 129 of the processing chamber 100.

The processing chamber 100 includes an upper electrode (e.g., the chamber lid 123) and a lower electrode (e.g., the substrate support assembly 136) positioned in the processing volume 129 of the processing chamber 100. The upper and lower electrodes face one another. In one embodiment, the RF generator 171 is electrically coupled to the lower electrode. The RF generator 171 is configured to deliver an RF signal to ignite and maintain the plasma 101 between the upper and lower electrodes. In some alternative configurations, the RF generator 171 can also be electrically coupled to the upper electrode. For example, the RF generator 171 may deliver an RF source power to an RF baseplate within a cathode assembly (e.g., in the substrate support assembly 136) for plasma production, whereas the upper electrode is grounded. A center frequency of the RF source power can be from 13.56 MHz to very high frequency band such as 40 MHZ, 60 MHZ, 120 MHz or 162 MHZ. In some examples, the RF source power can also be delivered through the upper electrode. The RF source power can be operated in a continuous mode or a pulsed mode. The RF power may have a pulsing frequency from 100 Hz to 10 kHz, and duty cycle ranging from 5% to 95%. The RF generator 171 has frequency tuning capability and can adjust the RF power frequency within e.g., ±5% or ±10%. In some embodiments, the RF generator 171 switches the RF power frequency at a predefined speed (e.g., two nanoseconds, fifty nanoseconds, etc.).

The substrate support assembly 136 may be coupled to a high voltage supply 173 that supplies a chucking voltage thereto. The RF generator 171 and the high voltage supply 173 may be coupled to a junction box 178 that is disposed between the high voltage supply 173 and the substrate support assembly 136.

The substrate support assembly 136 is coupled to the RF generator 171 which is configured to deliver an RF signal to the processing volume 129 of the processing chamber 100. The RF generator 171 is electrically coupled to the junction box 178 via an RF match 172. For example, the RF match 172 is an electrical circuit used between the RF generator 171 and a plasma reactor (e.g., the processing volume 129 of the processing chamber 100) to optimize power delivery efficiency. One or more RF filters (e.g., within the RF match 172, or the junction box 178) are designed to only allow powers in a selected frequency range, and to isolate RF power supplies from each other. In some cases, a bandwidth of an RF filter has to be larger than a frequency tuning range of the RF generator 171. The RF match 172 may or may not be included in the junction box 178.

During plasma processing, the RF generator 171 delivers an RF signal to the substrate support assembly 136 via the junction box 178. From the substrate support assembly 136, the RF signal is applied to a load (e.g., gas) in the processing volume 129 of the processing chamber 100. If an impedance of the load is not properly matched to an impedance of a source (e.g., the RF generator 171), a portion of a waveform can reflect back in an opposite direction. Accordingly, to prevent a substantial portion of the waveform from reflecting back, a match impedance (e.g., a matching point) is maintained by adjusting one or more components of the RF match 172 as the source and load impedances change.

The RF match 172 is electrically coupled to the RF generator 171, the substrate support assembly 136, and the PV waveform generator 175. The RF match 172 is configured to receive a synchronization signal from either or both of the RF generator 171 and the PV waveform generator 175.

The PV waveform generator 175 is used to supply a PV waveform and/or a tailored voltage waveform, which is a sum of harmonic frequencies associated with the waveform. The PV waveform generator 175 may output a synchronization TTL signal to the RF match 172. The PV waveform generator 175 and the RF generator 171 are coupled to a same electrode of the substrate support assembly 136 (e.g., substrate support base 107 shown in FIG. 1B) through the junction box 178. The high voltage supply 173 is applied to an electrode of the substrate support (e.g., biasing electrode 104 shown in FIG. 1B) to chuck a wafer during a process for thermal control. In some cases, there can be a third electrode at an edge of the substrate support assembly 136 for edge uniformity control.

The RF generator 171 and the PV waveform generator 175 are each directly coupled to a system controller 126. The system controller 126 synchronizes the respective generated RF signal and PV waveform.

FIG. 1B is a schematic detailed cross-sectional view of the plasma processing system 10. In one configuration, as shown in FIG. 1B, the plasma processing system 10 is configured to form a capacitively coupled plasma (CCP). However, in some embodiments, a plasma 101 may alternately be generated by use of an inductively coupled source disposed over the processing volume 129 of the plasma processing system 10. In this configuration, a coil may be placed on top of a ceramic lid (vacuum boundary) of the processing chamber 100.

The plasma processing system 10 includes the processing chamber 100, the substrate support assembly 136, the gas delivery system 182, an RF power system 189, and a system controller 126. As shown in FIG. 1, the processing chamber 100 includes a chamber body 113 that comprises a chamber lid 123, one or more sidewalls 122, and a chamber base 124. The chamber lid 123, one or more sidewalls 122, and the chamber base 124 collectively define the processing volume 129. The one or more sidewalls 122 and chamber base 124 generally include materials (such as aluminum, aluminum alloys, or stainless steel alloys) that are sized and shaped to form the structural support for the elements of the processing chamber 100. The one or more sidewalls 122 and chamber base 124 are configured to withstand the vacuum pressures and energy used to sustain a plasma 101 within the processing volume 129 of the processing chamber 100. A substrate 103 is loaded into, and removed from, the processing volume 129 through an opening (not shown) in one of the sidewalls 122. The opening is sealed with a slit valve (also not shown) during plasma processing of the substrate 103.

The gas delivery system 182, which is coupled to the processing volume 129 of the processing chamber 100, includes a processing gas source 119 and a gas inlet 128 disposed through the chamber lid 123. The gas inlet 128 is configured to deliver one or more processing gases to the processing volume 129 from the plurality of processing gas sources 119.

The processing chamber 100 further includes an upper electrode (e.g., chamber lid 123) and the substrate support assembly 136 that are disposed in a processing volume 129. As shown in FIG. 1B, in one embodiment, a radio frequency (RF) generator 171 is electrically coupled to a lower electrode (e.g., substrate support base 107) disposed within the substrate support assembly 136. The RF generator 171 is configured to deliver an RF signal to ignite and maintain the plasma 101 between the upper and lower electrodes. In some alternative configurations, the RF generator 171 can also be electrically coupled to an upper electrode, such as the chamber lid 123.

The substrate support assembly 136 includes a substrate support 105, a substrate support base 107, an insulator plate 111, a ground plate 112, a plurality of lift pins 186, one or more substrate potential sensing assemblies 184, and a biasing electrode 104. The substrate potential sensing assemblies 184 include a signal detecting assembly 188 and one or more sensors 190. The substrate potential sensing assembly 184 is communicatively coupled to the system controller 126 via communication line 165. The signal detection assembly 188 generally includes components that are configured to receive a signal from a sensor 190 and form an output signal that can be used by the system controller 126. The system controller 126 can then use the received output signal to display a result or measurement performed by the sensor 190 and/or control some part of the processing chamber 100 or process performed therein. The system controller 126, can transform the output signal received from the sensor into meaningful plasma diagnostic signals including, but not limited to, the Vdc (plasma voltage on the wafer), ion flux, or other parameters that can be used for chamber matching, fault detection, or improved control of the RF generator 171, and/or the PV generator. The one or more sensors 190 are coupled to the signal detection assembly 188 via the one or more communication lines 158. Each of the lift pins 186 are disposed through a through hole 185 formed in the substrate support assembly 136 and are used to facilitate the transfer of the substrate 103 to and from a substrate receiving surface 105A of the substrate support 105. The substrate support 105 is formed of a dielectric material. The dielectric material can include a bulk sintered ceramic material, a corrosion-resistant metal oxide (for example, aluminum oxide (Al₂O₃), titanium oxide (TiO), yttrium oxide (Y₂O₃), a metal nitride material (for example, aluminum nitride (AlN), titanium nitride (TiN)), mixtures thereof, or combinations thereof.

The substrate support base 107 is formed of a conductive material (for example aluminum, an aluminum alloy, or a stainless steel alloy). The substrate support base 107 is electrically isolated from the chamber base 124 by the insulator plate 111, and the ground plate 112 interposed between the insulator plate 111 and the chamber base 124. In some embodiments, the substrate support base 107 is configured to regulate the temperature of both the substrate support 105, and the substrate 103 disposed on the substrate support 105 during substrate processing. In some embodiments, the substrate support base 107 includes one or more cooling channels (not shown) disposed therein that are fluidly coupled to, and in fluid communication with, a coolant source (not shown), such as a refrigerant source or substrate source having a relatively high electrical resistance. In other embodiments, the substrate support 105 includes a heater (not shown) to heat the substrate support 105 and substrate 103 disposed on the substrate support 105.

A biasing electrode 104 is embedded in the dielectric material of the substrate support 105. Typically, the biasing electrode 104 is formed of one or more electrically conductive parts. The electrically conductive parts typically include meshes, foils, plates, or combinations thereof. In some embodiments, the biasing electrode 104 can function as a chucking pole (i.e., electrostatic chucking electrode) that is used to secure (e.g., electrostatically chuck) the substrate 103 to the substrate receiving surface 105A of the substrate support 105. In general, a parallel plate like structure is formed by the biasing electrode 104 and a layer of the dielectric material that is disposed between the biasing electrode 104 and the substrate receiving surface 105A. The dielectric material can typically have an effective capacitance CE of between about 5 nF and about 50 nF. Typically, the layer of dielectric material (e.g., aluminum nitride (AlN), aluminum oxide (Al₂O₃), etc.) has a thickness between about 0.03 mm and about 5 mm, such as between about 0.1 mm and about 3 mm, such as between about 0.1 mm and about 1 mm, or even between about 0.1 mm and 0.5 mm. The biasing electrode 104 is electrically coupled to a clamping network, which provides a chucking voltage thereto. The clamping network includes the high voltage supply 173 that is coupled to a bias compensation module (BCM) 178A of the junction box 178 that is disposed between the high voltage supply 173 and biasing electrode 104.

In some configurations, the substrate support assembly 136, further includes an edge control electrode 115. The edge control electrode 115 is formed of one or more electrically conductive parts. The electrically conductive parts typically include meshes, foils, plates, or combinations thereof. The edge control electrode 115 is positioned below the edge ring 114 and surrounds the biasing electrode 104 and/or is disposed a distance from a center of the biasing electrode 104. In general, for a processing chamber 100 that is configured to process circular substrates, the edge control electrode 115 is annular in shape, is made from a conductive material, and is configured to surround at least a portion of the biasing electrode 104. As seen in FIG. 1B, the edge control electrode 115 is positioned within a region of the substrate support 105, and is biased by use of an output provided from the high voltage supply 173. In one configuration, the edge control electrode 115 is biased by use of a PV waveform generator that is different from the PV waveform generator 175 used to biasing electrode 104. In another configuration, the edge control electrode 115 is biased by splitting part of the signal provided from the PV waveform generator 175 to the biasing electrode 104.

As shown in FIG. 1B, plasma processing system 10 includes the high voltage supply 173, the PV waveform generator 175, and a current source (not shown). In one example, the current source is included in the high voltage supply 173. In another example, the current source is separate from the high voltage supply 173. The RF power system 189 includes a radio frequency (RF) generator 171 and RF match 172.

In some embodiments, a junction box 178 is electrically coupled to one or more components of both the RF power system 189 and the high voltage supply 173. The junction box 178 electrically isolates one or more of the components contained within the RF power system 189 and the high voltage supply 173. Additionally, the junction box 178 is configured to decouple the high voltage supply 173 and the PV waveform generator 175, as described above, to reduce the current provided to biasing electrode 104, reduce arcing, allows for a PV waveform with a higher voltage, and increase the voltage margin of the PV waveform generator 175 while maintaining the same etch rate. In one example, the junction box 178 routes the outputs of the RF generator 171 and the PV waveform generator 175 to the substrate support base 107 and routes the output of the high voltage supply 173 to the biasing electrode 104.

In one example, the junction box 178 includes an RF filter 174, BCM 178A, a pulsed voltage (PV) filter 178B, a high voltage module (HVM) filter 178C, and sensor 190. In various embodiments, the junction box 178 is electrically coupled to the RF match 172, the high voltage supply 173, and the PV waveform generator 175. In other embodiments, the RF match 172 is included in the junction box 178 and the junction box is directly electrically coupled to the RF generator 171.

In some embodiments, the high voltage supply 173 is coupled to the biasing electrode 104 disposed within the substrate support assembly 136. The high voltage supply 173 is configured to supply a chucking voltage to the biasing electrode 104. The high voltage supply 173 is coupled to the biasing electrode via junction box 178. Power delivery line 160A electrically connects the output of the high voltage supply 173 to the BCM 178A of junction box 178. In one example, the BCM 178A is a circuit configured to keep the chucking voltage stable and eliminate the effects of pulse-off. Power delivery line 160B electrically connects the output of BCM 178A to a high voltage module (HVM) filter 178C of junction box 178. In one example, the HVM filter 178C is configured to isolate the high voltage supply 173 from other signals created within the processing chamber 100. For example, HVM filter 178C is configured to isolate the high voltage supply 173 from the signals generated from the RF generator 171 and the PV waveform generator 175. The HVM filter 178C may be any suitable filter that can protect the high voltage supply 173 such as a low-pass filter, a high-pass filter, a band-pass filter, or the like. In one example, the HVM filter 178C is a low pass filter.

Power delivery line 160C electrically connects the output of HVM filter 178C to biasing electrode 104. The HVM filter 178C removes interference from the RF and PV waveforms from getting back to the high voltage supply 173. In one configuration, the chucking voltage (i.e., static DC voltage) supplied by the high voltage supply 173 is between about −5000V and about 5000V, and is delivered using an electrical conductor (such as a coaxial power delivery lines 160A-160C).

In some embodiments, the PV waveform generator 175 is coupled to the substrate support base 107. In one example, the PV waveform generator 175 is configured to deliver a pulse voltage (PV) waveform to the substrate support base 107 to bias the substrate support assembly 136. Power delivery line 161A electrically connects the output of the PV waveform generator 175 to PV filter 178B of junction box 178. In one example, PV filter 178B is configured to isolate the PV waveform generator 175 from other signals created within the processing chamber 100. For example, PV filter 178B is configured to isolate the PV waveform generator 175 from the signals generated from the RF generator 171 and the high voltage supply 173. PV filter 178B may be any suitable filter that can protect the PV waveform generator 175 such as a low-pass filter, a high-pass filter, a band-pass filter, or the like. In one example, the frequency of the PV waveform and the frequency of the PV filter 178B are the same. In another example the frequency of the PV waveform and the PV filter 178B are different. Power delivery line 161B electrically connects the output of PV filter 178B to output node n1.

In some embodiments, the RF generator 171 is configured to deliver an RF waveform (also known as an RF bias voltage signal) to bias the substrate support base 107 to ignite and maintain a plasma 101 in a processing volume 129 of the processing chamber 100. Power delivery line 163A electrically connects the output of the RF generator 171 to the RF match 172. The RF match 172 includes an RF matching network that tunes the RF waveform provided by the RF generator 171 to minimize the reflected power and improve the power delivery efficiency. If the impedance of the load is not properly matched to the impedance of the source (e.g., the RF generator), a portion of the RF waveform can reflect back in the opposite direction along the same transmission line. Stated differently, the RF match 172 is configured to receive an RF waveform from the RF generator 171, tune/match the impedance of the load to the impedance of the generator to reduce the reflected power and improve power delivery efficiency, and deliver the tuned RF waveform to the processing chamber 100. Power delivery line 163B electrically connects the output of the RF match 172 to RF filter 174 of junction box 178. In one example, RF filter 174 is configured to isolate the RF generator 171 from other signals created within the processing chamber 100. For example, RF filter 174 is configured to isolate the RF generator 171 from the signals generated from the PV waveform generator 175 and the high voltage supply 173. The RF filter 174 may be any suitable filter that can protect the RF generator 171 such as a low-pass filter, a high-pass filter, a band-pass filter, or the like. In one example, the frequency of the RF signal and the frequency of the RF filter 174 are the same. In another example the frequency of the RF signal and the RF filter 174 are different.

Power delivery line 163C electrically connects the output of the RF filter 174 to output node n1. Power delivery line 164A electrically connects output node n1 to sensor 190. Power delivery line 164B electrically connects the output of sensor 190 to substrate support base 107. Alternatively, sensor 190 and power delivery line 164B are optional and power delivery line 164A is electrically connected to substrate support base 107. In one configuration, the RF waveform has a frequency range between about 100 kHz and about 200 MHz, such as between 2 MHz and 40 MHz.

The power delivery lines 160-164B include electrical conductors that include a combination of coaxial cables, such as a flexible coaxial cable that is connected in series with a rigid coaxial cable, an insulated high-voltage corona-resistant hookup wire, a bare wire, a metal rod, an electrical connector, of any combination of the above.

The system controller 126, also referred to herein as a processing chamber controller, includes a central processing unit (CPU) 133, a memory 134, and support circuits 135. The system controller 126 is used to control the process sequence used to process the substrate 103. The CPU is a general-purpose computer processor configured for use in an industrial setting for controlling the processing chamber and sub-processors related thereto. The memory 134 described herein, which is generally non-volatile memory, can include random access memory, read-only memory, hard disk drive, or other suitable forms of digital storage, local or remote. The support circuits 135 are conventionally coupled to the CPU 133 and comprises cache, clock circuits, input/output subsystems, power supplied, and the like, and combinations thereof. Software instructions (program) and data can be coded and stored within the memory 134 for instructing a processor within the CPU 133. A software program (or computer instructions) readable by CPU 133 in the system controller 126 determines which tasks are performable by the components in the plasma processing system 10.

Typically, the program, which is readable by the CPU 133 in the system controller 126 includes code, which, when executed by the CPU 133, performs tasks relating to the plasma processing schemes described herein. The program may include instructions that are used to control the various hardware and electrical components within the plasma processing system 10 to perform the various process tasks and various process sequences.

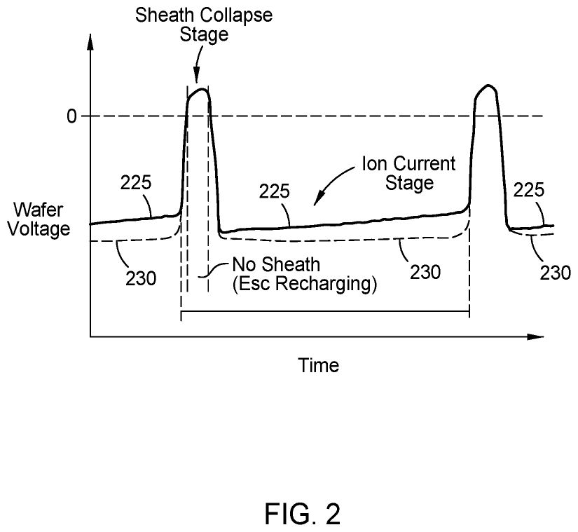

FIG. 2 illustrates two separate voltage waveforms established at the substrate 103 disposed on the substrate receiving surface 105A of the substrate support assembly 136 of the processing chamber 100 due to the delivery of PV waveforms to the biasing electrode 104 of the processing chamber 100. A first waveform (e.g., a waveform 225) is an example of a non-compensated PV waveform established at the substrate 103 during the plasma processing. A second waveform (e.g., a waveform 230) is an example of a compensated PV waveform established at the substrate 103 by applying a negative slope waveform to the substrate support base 107 of the processing chamber 100 during an “ion current stage” portion of the PV waveform cycle by use of a current source. The compensated PV waveform can alternatively be established by applying a negative voltage ramp during the ion current stage of the PV waveform generated by the PV waveform generator 175.

The waveforms 225 and 230 include two main stages: an ion current stage and a sheath collapse stage. Both portions (e.g., the ion current stage and the sheath collapse stage) of the waveforms 225 and 230, can be alternately and/or separately established at the substrate 103 during the plasma processing. Conventionally, at a beginning of the ion current stage, a drop in the voltage at the substrate 103 is created, due to the delivery of a negative portion of the PV waveform (e.g., the ion current portion) provided to the substrate support base 107 by the PV waveform generator 175, which creates a high voltage sheath above the substrate 103. The high voltage sheath allows the plasma generated positive ions to be accelerated towards the biased substrate 103 during the ion current stage, and thus, for RIE processes, controls the amount and characteristics of the etching process that occurs on the surface of the substrate 103 during the plasma processing. In some embodiments, it is desirable for the ion current stage to include a region of the PV waveform that achieves the voltage at the substrate 103 that is stable or minimally varying throughout the stage, as illustrated in FIG. 2 by the waveform 230. One will note that providing the PV waveform to the substrate support base 107 instead of the biasing electrode 104 reduces the voltage overshoot, ringing, and current spikes provided to the biasing electrode 104 of a plasma processing chamber 100, which reduces arcing, allows for a PV waveform with a higher voltage, and increases the margin of the voltage provided by the PV waveform generator 175 to the plasma processing chamber 100.

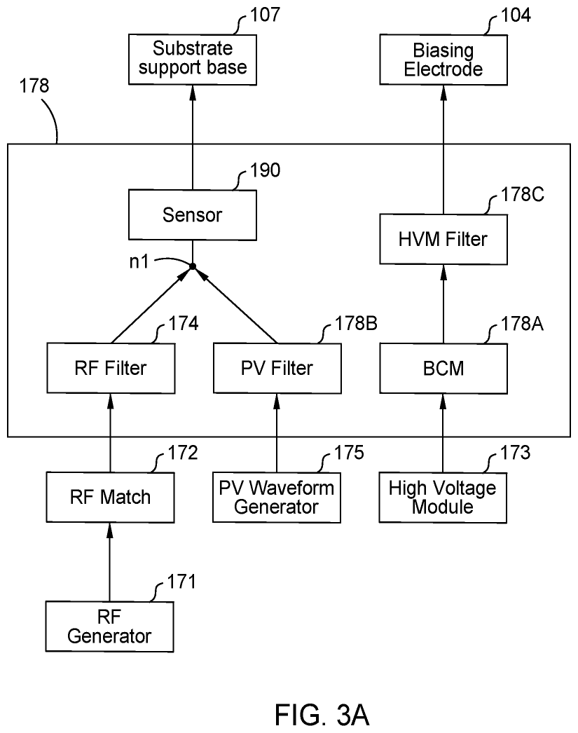

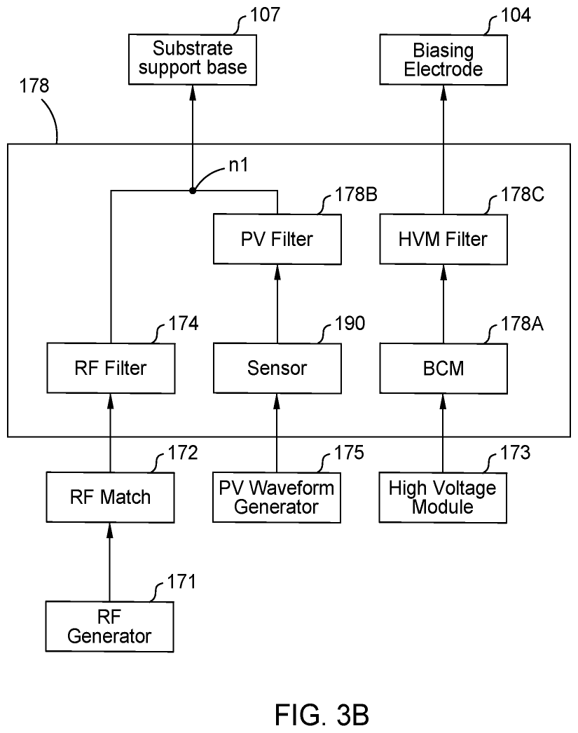

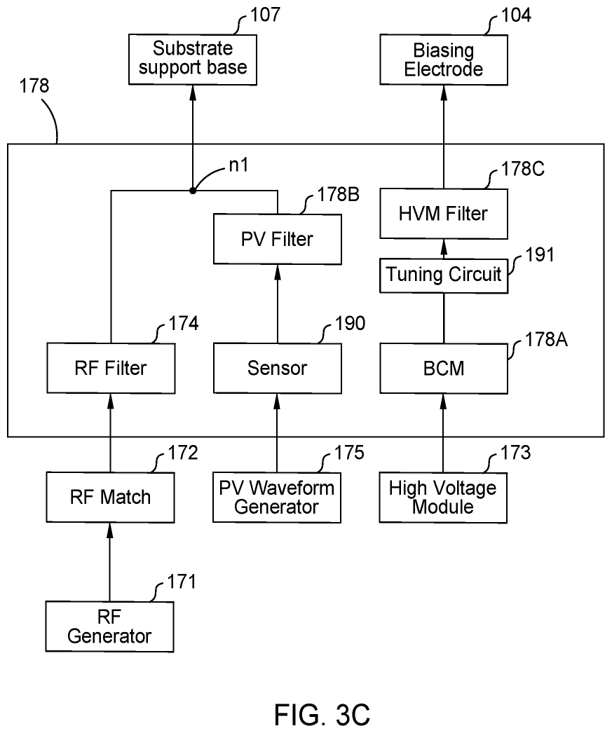

FIG. 3A is a schematic representation of a junction box 178 according to one or more embodiments. The junction box 178 may include RF filter 174, BCM 178A, PV filter 178B, HVM filter 178C, and sensor 190. In one example, the junction box 178 receives inputs from the RF match 172, the PV waveform generator 175, and the high voltage supply 173. In another example, the RF match 172 is included in the junction box 178 and the RF generator 171 is directly coupled to the junction box 178.

The RF filter 174 is electrically coupled to the RF match 172. The PV filter 178B is electrically coupled to the PV waveform generator 175. The BCM 178A is electrically coupled to the high voltage supply 173. The input of the sensor 190 is electrically coupled to the RF filter 174 and the PV filter 178B via output node n1. The output of the sensor 190 is electrically coupled to the substrate support base 107. The input of the HVM filter 178C is electrically coupled to the BCM 178A. The output of the HVM filter 178C is electrically coupled to the biasing electrode 104.

Each of the filters is configured to isolate a corresponding signal generator from the other signals provided and generated in the processing chamber. For example, RF filter 174 is configured to block the RF generator 171 from the signals generated from the PV waveform generator 175 and the high voltage supply 173 to avoid interference. PV filter 178B is configured to block the PV waveform generator 175 from the signals generated from the RF generator 171 and the high voltage supply 173 to avoid interference. HVM filter 178C is configured to block the high voltage supply 173 from the signals generated from the PV waveform generator 175 and the RF generator 171 to avoid interference.

In one example, the sensor 190 may include a voltage sensor and/or a current sensor configured to measure the impedances or the characteristics of the plasma processing system 10. The sensor 190 may include a voltage sensor and/or a current sensor configured to measure characteristics of the RF signal and the PV waveform such as voltage, current, phase, or harmonics. Sensor readings can be used in a feedback and feedforward algorithms for impedance matching. In one example, the sensor 190 may be coupled to an RF match controller 302 of the RF match 172, and/or PV waveform generator 175. In another example, the sensor 190 is coupled to the RF match controller 302 and the RF match controller 302 provides the readings from the sensor 190 to the PV waveform generator 175 and/or the system controller 126. In one example, based on the readings by the sensor 190 the RF match controller 302 adjusts the matching point of the RF match 172 so that the impedance of the output signal provided by the junction box 178 matches the impedance of the plasma processing chamber 100. In another example, based on the readings from the sensor 190, the PV waveform generator 175 adjusts properties of the PV waveform including, but not limited to, the rising and falling edges of the PV waveform, the duty cycle of the PV waveform, and the voltage of the PV waveform. In another example, the sensor 190 communicates to directly the system controller 126 and the system controller 126, based on the readings of the senor, adjusts the PV and RF waveforms accordingly via the RF generator 171 and the PV waveform generator 175. Based on the readings from the sensor 190, the RF generator adjusts properties of the RF waveform including, but not limited to, the power and/or pulsing of the RF waveform. In another example, the sensor 190 is optional.

FIG. 3B is a schematic representation of a junction box 178 according to one or more embodiments. In one example, the input of the sensor 190 is electrically connected to the output of the PV waveform generator 175. The output of the sensor 190 is electrically connected to the PV filter 178B. The outputs of the RF filter 174 and the PV filter 178B are both electrically connected to the substrate support base 107 via output node n1.

FIG. 3C is a schematic representation of a junction box 178 according to one or more embodiments. In one example, the junction box 178 includes tuning circuit 191 electrically coupled between the output of the BCM 178A and the biasing electrode 104. The tuning circuit 191 is coupled to the biasing electrode 104 via the HVM filter 178C. In one example, the tuning circuit 191 includes at least one variable capacitor and is configured to control the PV waveform and controls overshoots on the substrate to ensure a fast etch rate while maintaining stability.

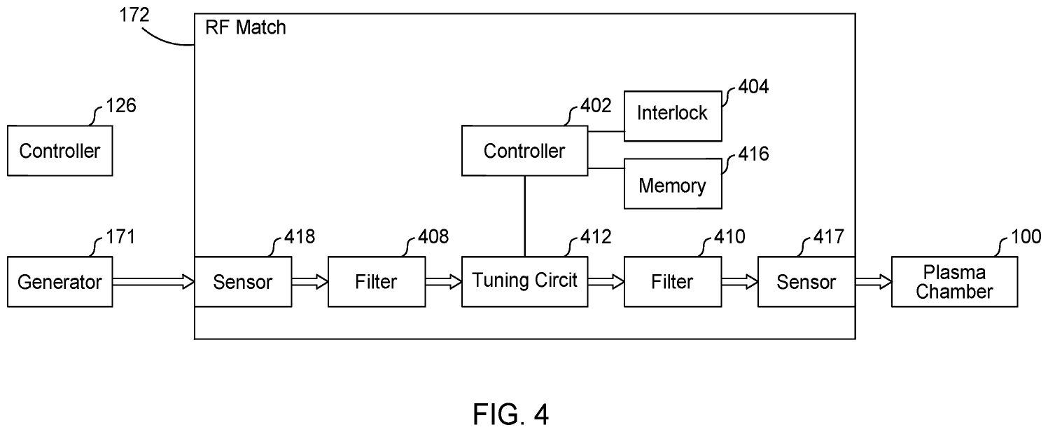

FIG. 4 is a schematic representation of a RF power delivery system, according to one or more embodiments. The RF match 172 includes an RF match controller 402, input sensor 418, and output sensor 417, a first RF filter 408, a second RF filter 410, a tuning circuit 412, an interlock 414, and a memory 416. The first RF filter 408 and the second RF filter 410 may be configured to block frequencies from other signals being transmitted from the processing chamber 100 to avoid interference at the RF generator 171. For example, the first RF filter 408 and the second RF filter 410 may be low pass, high pass, or band pass filters.

The RF match 172 is configured to receive an RF waveform from the RF generator 171, tune the RF waveform to reduce the reflected power and improve power delivery efficiency. For the advantages explained above, the RF match 172 delivers the tuned RF waveform to substrate support base 107 of processing chamber 100 via junction box 178. In some embodiments, as described above, the PV waveform generator 175 is configured to provide a PV waveform to substrate support base 107 of processing chamber 100 simultaneously with the tuned RF waveform. The RF generator 171 and the PV waveform generator 175 are both communicationally coupled to and synchronized by the system controller 126. The synchronization signal can be from the system controller 126, the PV waveform generator 175 or the RF generator 171.

The RF match controller 402 may be communicationally coupled to the interlock 414, the memory 416, the tuning circuit 412, the input sensor 418, the output sensor 417, and optionally, sensor 190 (FIGS. 3A and 3C). In some embodiments, the RF match controller 402 is also in communication with an electronic device that includes a display and user interface, such as conventional computer (e.g., user PC), which may in some cases form part of the system controller 126. The RF match controller 402 includes a central processing unit (CPU). The RF match controller 402 is configured to control the tuning circuit 412 to change an impedance parameter of the RF match 172. The tuning circuit 412 described herein may be a T-network tuning circuit, a pi-network tuning circuit, an L-network circuit, or the like. The tuning circuit 412 may include at least one electrical component, such as a variable capacitor and/or inductor that can be adjusted by the RF match controller 402 to change the impedance, so that the RF waveform delivered to the processing chamber 100 has been optimized. Thus, generating an adjusted RF signal. The tuning circuit 412 has an input 412A that is directly or indirectly coupled to the input sensor 418 and output 412B that is directly or indirectly coupled to the output sensor 417.

The memory 416 may be programmed for long term or short term memory storage. The memory 416 described herein, which is generally non-volatile memory, can include random access memory, read-only memory, hard disk drive, or other suitable forms of digital storage, local or remote. Software instructions (program) and data can be coded and stored within the memory 416 for instructing a processor within the controller 402. A software program (or computer instructions) readable by controller 402 determines which tasks are performable by the components in the plasma processing system 10.

The interlock 414 is implemented for safety purposes to control over temperature switches, cable-in-place switches, and match-in-place switches, etc. The interlock 414 is open when failure happens, and an interlock signal will be sent from a local microcontroller to both a user laptop and the system controller 126 to shut the system off.

The output sensor 417 may include a voltage sensor and/or a current sensor configured to measure the impedances or the characteristics of the plasma processing system 10 explained above. In some embodiments, when the sensor 190 (FIGS. 3A and 3C) is included in the junction box 178, the output sensor 417 is optional. If the sensor 190 is not included in the junction box 178, the output sensor 417 is included in the RF match 172. The output sensor 417 can be located between the RF match 172 and the junction box 178, or may be included within the junction box 178. Stated differently, the output sensor 417 and/or sensor 190 can be located anywhere between the output of the RF match 172 and the substrate support base 107. The input sensor 418 may include a voltage sensor and/or a current sensor configured to measure characteristics of the RF waveform such as voltage, current, phase, or harmonics. In some cases, only one sensor can be used at the input of the RF match 172. Sensor readings can be used in a feedback and feedforward algorithms for impedance matching.

Advantageously, as described above, the junction box 178 routes both a tuned RF waveform from the RF generator 171 and a PV waveform from PV waveform generator 175 to substrate support base 107. This effectively decouples the PV waveform generator 175 from biasing electrode 104 and reduces the current provided to biasing electrode 104, reduces arcing, allows for a PV waveform with a higher voltage, and increases the voltage margin of the PV waveform generator 175 while maintaining the same etch rate.

While the foregoing is directed to embodiments of the present disclosure, other and further embodiments of the disclosure may be devised without departing from the basic scope thereof, and the scope thereof is determined by the claims that follow.

What is claimed is:

1. A plasma processing system comprising:
a radio frequency (RF) generator coupled to a substrate support base disposed within the plasma processing system and configured to deliver an RF signal to the substrate support base;
a pulsed voltage (PV) waveform generator coupled the substrate support base and configured to deliver a PV waveform to the substrate support base while the RF signal is delivered to the substrate support base; and
a high voltage supply coupled to a biasing electrode of the plasma processing system and configured to deliver a chucking voltage to a biasing electrode disposed within the plasma processing system.

2. The plasma processing system of claim 1, wherein an output of the RF generator is coupled to the substrate support base and configured to deliver the RF signal to the substrate support base, and wherein an output of the PV waveform generator is coupled to the substrate support base and configured to deliver the PV waveform to the substrate support base, and wherein an output of the high voltage supply is coupled to the biasing electrode and configured to deliver the chucking voltage to the biasing electrode through a junction box.

3. The plasma processing system of claim 2, wherein the junction box comprises:
a bias compensation module (BCM) coupled to the high voltage supply and configured to receive the chucking voltage from the high voltage supply and stabilize the chucking voltage; and
a high voltage module (HVM) filter coupled to an output of the BCM and configured to receive the chucking voltage and provide the chucking voltage to the biasing electrode.

4. The plasma processing system of claim 2, wherein the junction box comprises:
a bias compensation module (BCM) coupled to the high voltage supply and configured to receive the chucking voltage from the high voltage supply and stabilize the chucking voltage;
a tuning circuit coupled to an output of the BCM and configured to control the PV waveform.
a high voltage module (HVM) filter coupled to an output of the tuning circuit and configured to receive the chucking voltage and provide the chucking voltage to the biasing electrode.

5. The plasma processing system of claim 2, further comprising an RF match configured to be coupled to the RF generator and configured to receive the RF signal from the RF generator, adjust the RF signal, and provide the RF signal to the junction box.

6. The plasma processing system of claim 5, wherein the junction box comprises an RF filter coupled to an output of the RF match and configured to receive the RF signal from the RF match and provide the RF signal to the substrate support base.

7. The plasma processing system of claim 2, wherein the junction box further comprises a PV filter coupled to the PV waveform generator and configured to receive the PV waveform from the PV waveform generator and provide the PV waveform to the substrate support base.

8. The plasma processing system of claim 5, wherein the junction box comprises:
an RF filter coupled to the RF match and configured to receive the RF signal from the RF match and provide the RF signal to a sensor located between the RF match and the substrate support base;
a PV filter coupled to the PV waveform generator and configured to receive the PV waveform from the PV waveform generator and provide the PV waveform to the sensor, wherein the sensor disposed in the junction box, is coupled to an RF match controller of the RF match, and is configured to measure characteristics of the RF signal and the PV waveform and provide the measured characteristics to at least one of the RF match controller and the PV waveform generator.

9. A plasma processing system comprising:
an radio frequency (RF) generator configured to generate an RF signal;
a pulsed voltage (PV) waveform generator configured to generate a PV waveform;
a high voltage supply configured to generate a chucking voltage; and
a junction box coupled to the RF generator, the PV waveform generator, and the high voltage supply, the junction box configured to receive the RF signal, the PV waveform, and the chucking voltage, supply the RF signal and the PV waveform to a substrate support base of the plasma processing system, and supply the chucking voltage to a biasing electrode of the plasma processing system.

10. The plasma processing system of claim 9, wherein the junction box comprises:
a bias compensation module (BCM) coupled to the high voltage supply and configured to receive the chucking voltage from the high voltage supply and stabilize the chucking voltage; and
a high voltage module (HVM) filter coupled to an output of the BCM and configured to receive the chucking voltage and provide the chucking voltage to the biasing electrode.

11. The plasma processing system of claim 9, wherein the junction box comprises:
a bias compensation module (BCM) coupled to the high voltage supply and configured to receive the chucking voltage from the high voltage supply and stabilize the chucking voltage;
a tuning circuit coupled to an output of the BCM and configured to control the PV waveform.
a high voltage module (HVM) filter coupled to an output of the tuning circuit and configured to receive the chucking voltage and provide the chucking voltage to the biasing electrode.

12. The plasma processing system of claim 9, further comprising an RF match coupled to the RF generator and configured to receive the RF signal from the RF generator, adjust the RF signal, and provide the RF signal to the junction box.

13. The plasma processing system of claim 12, wherein the junction box comprises an RF filter coupled to the RF match and configured to receive the RF signal from the RF match, and provide the RF signal to the substrate support base.

14. The plasma processing system of claim 12, wherein the junction box comprises:
an RF filter coupled to the RF match and configured to receive the RF signal from the RF match, and provide the RF signal to a sensor located between the RF match and the substrate support base;
a PV filter coupled to the PV waveform generator and configured to receive the PV waveform from the PV waveform generator and provide the PV waveform to the sensor, wherein the sensor is coupled to an RF match controller of the RF match, is configured to measure characteristics of the RF signal and the PV waveform, and provide the measured characteristics to at least one of the RF match controller and the PV waveform generator.

15. A junction box comprising:
A radio frequency (RF) filter coupled to an RF generator of a plasma processing system and configured to receive an RF signal from the RF generator;
a pulsed voltage (PV) filter coupled to a PV waveform generator of the plasma processing system and configured to receive an PV waveform from the PV waveform generator; and
a bias compensation module (BCM) coupled to a high voltage supply of the plasma processing system and configured to receive a chucking voltage from the high voltage supply, wherein the junction box is configured to transmit the RF signal and the PV waveform to a substrate support base of a plasma processing chamber of the plasma processing system and transmit the chucking voltage to a biasing electrode of the plasma processing chamber.

16. The junction box of claim 15, further comprising a high voltage module (HVM) filter coupled to an output of the BCM and configured to receive the chucking voltage and provide the chucking voltage to the biasing electrode.

17. The junction box of claim 15, further comprising:
a tuning circuit coupled to an output of the BCM configured to control the PV waveform; and
a high voltage module (HVM) filter coupled to an output of the tuning circuit and configured to receive the chucking voltage and provide the chucking voltage to the biasing electrode.

18. The junction box of claim 15, further comprising an RF filter coupled to an RF match of the plasma processing system and configured to receive the RF signal from the RF match, and provide the RF signal to the substrate support base.

19. The junction box of claim 15, further comprising a PV filter coupled to a PV waveform generator of the plasma processing system and configured to receive the PV waveform from the PV waveform generator and provide the PV waveform to the substrate support base.

20. The junction box of claim 15, wherein the junction box comprises:
an RF filter coupled to the RF match and configured receive the RF signal from the RF match, and provide the RF signal to a sensor located between the RF match and the substrate support base;
a PV filter coupled to the PV waveform generator and configured to receive the PV waveform from the PV waveform generator and provide the PV waveform to the sensor, wherein the sensor is coupled to at least one of an RF match controller of the RF match, the PV waveform generator and a system controller, and the sensor is configured to measure characteristics of the RF signal and the PV waveform, and provide the measured characteristics to at least one of the PV waveform generator, the RF match controller, and the system controller.
